(19) United States
(12) Patent Application Publication
(10) Pub. No.: US 2006/0028895 A1
(43) Pub. Date: Feb. 9, 2006

(54) Silver island anti-fuse

(76) Inventors: Carl Taussig, Redwood City, CA (US); Warren Jackson, San Francisco, CA (US); Craig Perlov, San Mateo, CA (US); Frank R. Jeffrey III, Armes, IA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/914,255

(22) Filed: Aug. 9, 2004

(51) Int. Cl. G11C 17/18; G11C 11/36

(52) U.S. Cl. 365/225.7; 365/175

(57) ABSTRACT

An silver island anti-fuse including a first electrical conductor, an electrically resistive material in contact with the first conductor and at least one silver island disposed opposite the first electrical conductor and upon the electrically resistive material. A second electrical conductor disposed over the silver island intimately couples the silver island to the electrically resistive material. When a critical potential is applied across the anti-fuse, a metallic filament precipitates from the silver island through the electrically resistive material layer, establishing a short and thus switching the silver island anti-fuse from a high resistance to a low resistance. A method of making the silver island anti-fuse and a memory device incorporating the silver island anti-fuse are further provided.

### FIELD OF THE INVENTION

The present invention relates generally to memory systems, and in particular to an improved method of making an anti-fuse incorporating silver islands.

### BACKGROUND

Most computers and electronic devices have memory components and memory elements that are used to store information. The variety of information stored is expansive. Typically, but not exclusively, this information may be operating system instructions, data undergoing processing, and/or data stored for later retrieval such as document files, image files, music files, program codes, etc.

Many devices, such as digital cameras for still and/or moving pictures, generate large amounts of digital information representing images. Generally speaking, a greater image resolution requires storage of larger amounts of digital information. A single high resolution image may easily require several megabytes of digital storage space.

The user of a digital camera may want to take more than one picture, and frequently may wish to use the camera in a portable fashion that is free of connections to external power supplies or storage devices. Music playing devices, such as MP3 players and other devices, are also frequently relied upon by their users to provide large storage capacity while also permitting portable use and enjoyment.

There are generally two user needs for memory devices used in these types of information storage applications. First, the memory devices should be physically small enough to be removably integrated into the device (i.e., the digital camera or MP3 player) while still providing enough storage capacity to be of beneficial use. Second, the memory devices should have a low power consumption. For truly portable devices, it is also desirable for the memory devices to have relatively rugged physical characteristics, so as to operate and survive in a variety of environments. From a manufacturing point of view, it is desirable to meet consumer demands with a memory device that is cost effective to produce.

Computer information is most easily stored, processed and otherwise manipulated in binary form—a series of logic states represented as “0” or “1”. The ability to store information, such as the logic state of a “0” or a “1” within a single memory device or memory media is therefore generally predicated upon the ability to establish one of two states such as, for example, a high resistance or a low resistance state.

There are also two generally accepted types of memory utilized in memory storage—volatile and non-volatile. Volatile memory is functional so long as power is continuously supplied. Upon removal of the power, the contents of the volatile memory will likely be significantly damaged, if not lost entirely. Typically, traditional main memory RAM in a computer is volatile memory.

In contrast, non-volatile memory is not power dependent, and will continue to hold the information placed within its store without significant degradation for an extended period of time. Non-volatile memory accomplishes this long term, power independent storage ability typically by changing a physical property such as, for example, changing the reflective property of a material as in a CD or DVD, the creation of bumps or dips in a polymer surface, or the alignment of a magnetic field provided by a media. Non-volatile memory may often be referred to as storage media.

With semiconductor based memory devices comprising individual memory elements, the relative state of resistance within each memory element may also indicate a stored data value. In other words a high resistance may indicate a binary “1” while a low resistance may indicate a binary “0”. Semiconductor based non-volatile memory devices are becoming increasingly common as more products requiring larger amounts of memory storage emerge, especially in portable form. For example, some early digital cameras utilized a 3.5″ floppy disc with 1.44 megabytes of memory for storing the digital information making up a picture. Contemporary digital cameras of today frequently create images that are far in excess of 1.44 megabytes and, as such, utilize semiconductor data storage chips providing 32, 64, 128 or more megabytes of storage.

Portable long term data storage devices typically are re-writable. In other words, information may be written to the device at one point in time and then later over-written with new information. The ability to provide re-writable characteristics in a non-volatile data storage device often increases the manufacturing complexity as well as the control logic and circuitry within the device, thus increasing the cost of such devices.

With respect to memory devices for portable electronic devices, such as digital cameras, music players, personal data assistants and the like, the vast majority of memory devices available are re-writeable. Frequently, the re-writeability of the storage device is not of high value or concern to the user. Indeed, more use and enjoyment might be experienced with single write, lower cost memory devices.

Hence, there is a need for an improved, non-volatile memory device and its components that overcomes one or more of the drawbacks identified above.

### SUMMARY

The present disclosure advances the art by providing a silver island anti-fuse and a related method of making the silver island anti-fuse.

In particular and by way of example only, according to an embodiment, an silver island anti-fuse is provided, including: a first electrical conductor; an electrically resistive material in contact with the first electrical conductor; a second electrical conductor in contact with the electrically resistive material, opposite from the first electrical conductor; and a plurality of silver islands at least partially disposed within one or both electrical conductors, the silver islands in contact with the electrically resistive material.

### BRIEF DESCRIPTION OF THE DRAWINGS

FIG. 1 is a mid sectional view of a silver island anti-fuse according to an embodiment;

FIG. 2 is a partial perspective view of the silver island anti-fuse shown in FIG. 1;

FIG. 3 is a mid sectional view of the silver island anti-fuse shown in FIG. 1 with a metallic filament developed from a silver island;

FIG. 4 is a mid sectional view of the silver island anti-fuse shown in FIG. 1 with a metallic diffusion barrier arresting the metallic filament shown in FIG. 3;

FIG. 5 provides a graph illustrating switching currents versus thickness of an amorphous silicon layer for device structures with and without silver;

FIG. 6 provides a graph illustrating switching voltages verses thickness of an amorphous silicon layer for device structures with and without silver;

FIG. 7 provides a graph illustrating the combined effect of scaling switch currents and voltages for device structures with and without silver;

FIG. 8 is a plan view of a memory device incorporating a plurality of cells incorporating the silver island anti-fuse device;

FIG. 9 provided additional detail with respect to one cell shown in FIG. 8 and identified as 9′;

FIG. 10 shows a first conductor formed in one process of making a silver island anti-fuse device;

FIG. 11 shows a resistive layer formed in one process of making a silver island anti-fuse device;

FIG. 12 shows a plurality of silver islands formed in one process of making a silver island anti-fuse device;

FIG. 13 shows a conductive material formed upon the silver islands in one process of making a silver island anti-fuse device;

FIG. 14 shows a diffusion barrier formed in one process of making a silver island anti-fuse device;

FIG. 15 shows a completed cell with a separate diffusion barrier resulting from at least one process of making a silver island anti-fuse; and

FIG. 16 is a transmission electron micrograph showing silver islands.

### DETAILED DESCRIPTION

Before proceeding with the detailed description, it is to be appreciated that the present teaching is by way of example, not by limitation. Thus, although the instrumentalities described herein are for the convenience of explanation shown and described with respect to exemplary embodiments, it will be appreciated that the principles herein may be equally applied in other types of memory devices. It will be appreciated that the drawings are not necessarily drawn to scale and may be expanded in certain aspects for ease of discussion.

In the following description, the term “data” is understood and appreciated to be represented in various ways depending upon context. Generally speaking, the data at issue is primarily binary in nature, represented as logic “0” and logic “1”. However, it will be appreciated that the binary states in practice may be represented by relatively different voltages, currents, resistances or the like that may be measured or sensed, and it may be a matter of design choice whether a particular practical manifestation of data within a memory element represents a “0” or a “1” or other memory state designation.

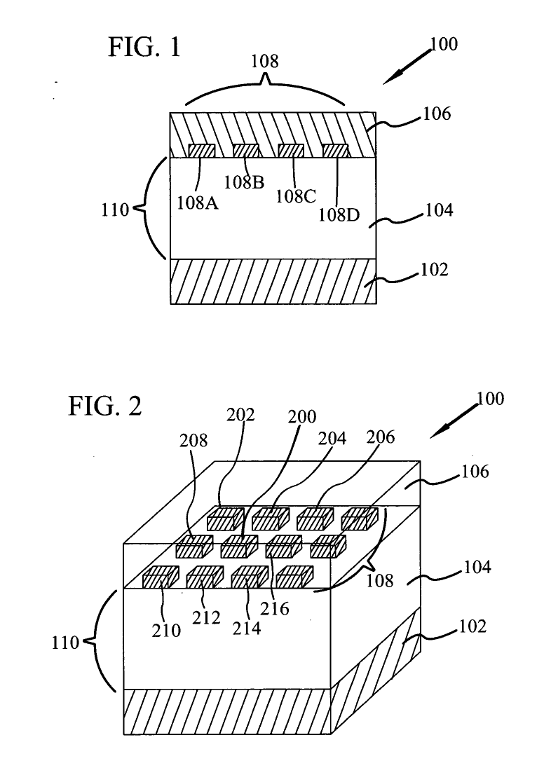

Referring now to the drawings, and more particularly to FIG. 1, there is shown a portion of a silver island anti-fuse (herein after “SIAF”) 100. In at least one embodiment, the SIAF 100 has a first electrical conductor (hereinafter first conductor 102), an electrically resistive material 104, a second electrical conductor (hereinafter second conductor 106), and at least one silver island 108A, 108B, 108C and 108D (collectively identified as silver islands 108).

More specifically, electrically resistive material 104 is in contact with the first conductor 102. Second conductor 106 is in contact with electrically resistive material 104, opposite from first conductor 102. At least one silver island, e.g silver island 108A, is at least partially disposed within one or both conductors 102 and 106, and in contact with the electrically resistive material 104. Conductors 102 and 106 may also be referred to as electrodes. In at least one embodiment, electrically resistive material 104 is an amorphous silicon layer 110.

FIG. 2 is a perspective view of the SIAF 100 shown in FIG. 1. With respect to FIG. 2, the nature of the silver islands 108 (including silver islands 200 through 216) may be more fully appreciated. Specifically, a plurality of silver islands 108 are disposed upon the electrically resistive material 104, opposite from the first conductor 102. As may be appreciated in the illustration, the silver islands 108 are not in direct physical contact with one another. For example, a specific silver island 200 is in direct physical contact with electrically resistive material 104, but silver island 200 is not in direct physical contact with its neighboring silver islands 202˜216. Electrical contact between the silver islands 108 is indirect through the resistive material 104 and second conductor 106.

Silver islands 108 may be advantageously provided without photolithographic etching processes or other feature defining processes. The resistive material 104 may be a poly silicon, a polymer, an oxide, or other material suitable for providing a high state of resistance between the first electrical conductor 102 and the second electrical conductor 106. As noted above, in at least one embodiment electrically resistive material 104 is an amorphous silicon layer.

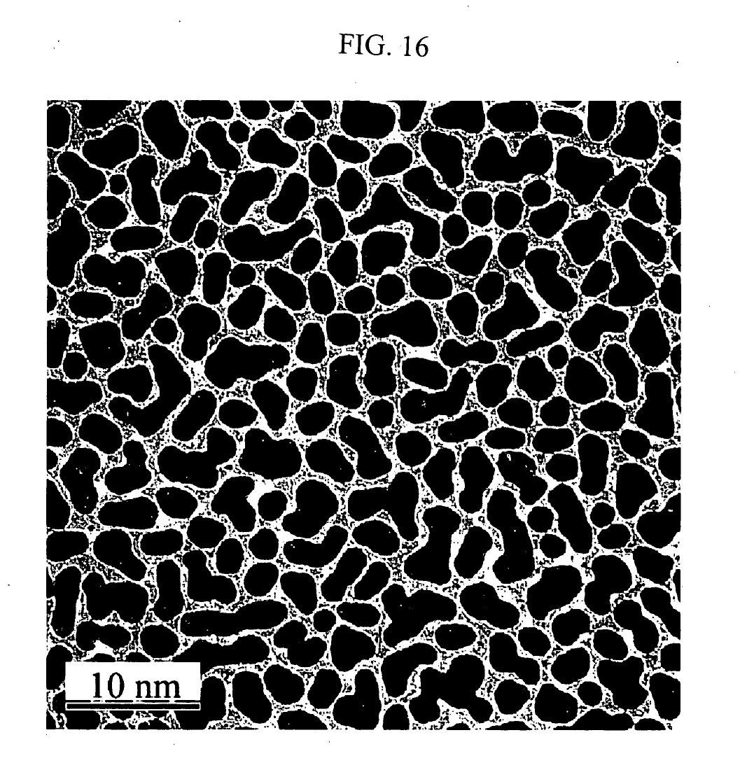

When a layer of silver less than 100 Å thick is deposited on silicon, silicon nitride or many other materials including amorphous silicon layer 110, the silver will not form a continuous film, but rather will break up into a series of islands of substantially the same size. The size of each silver island 108 is generally the same as the thickness of the silver layer deposited. More specifically, if the silver layer provided is 75 Å thick, the resulting silver islands 108 will be about 75 Å thick and average about 75 Å in diameter. In at least one embodiment, the silver islands 108 are deposited upon the resistive layer 104 by sputtering. FIG. 16 is a reproduction of a transmission electron micrograph of a layer of silver less than 100 Å thick deposited upon a silicon layer showing the development of silver islands.

In at least one preferred embodiment, first conductor 102 typically comprises chromium or another metal that has good adhesion properties to the amorphous silicon layer 110, and which is, of course, electrically conductive. In alternative embodiments, first conductor 102 may comprise titanium and or tungsten, metals also known to have good adhesion properties to amorphous silicon. The issue of adhesion property is in respect to the solid phase of the materials. Adhesion is a function of surface chemistry of the materials and the conditions of the deposition process. Amorphous silicon layer 110 is a non-crystalline form of silicon. Normal silicon is tetrahedrally bonded to four neighboring silicon atoms, and so may be the case with amorphous silicon. However, amorphous silicon does not form a continuous crystalline lattice as is found in crystalline silicon. Some silicon atoms may have dangling bonds, which occur when the silicon atom does not bond to four neighboring atoms. As not all of the silicon atoms are four-fold coordinated (connected to four other atoms), amorphous silicon is considered to be under-coordinated.

The dangling bonds of amorphous silicon introduce defects in the continuous random network of the amorphous silicon and provide an advantageous property of enabling the amorphous silicon to be used over larger areas than are usually covered by crystalline silicon. More specifically, as the amorphous silicon has numerous natural defects, any other defects, such as unintended impurities, do not substantially affect the overall characteristics of the material. The dangling bonds may be passivated by introducing hydrogen, thus achieving hydrogenated amorphous silicon. Further, amorphous silicon may be doped just as with traditional crystalline silicon to provide specific intended properties, e.g. n-type or p-type amorphous silicon.

Unlike crystalline silicon, amorphous silicon can also be deposited at low temperatures, for example, at 75 degrees Celsius. Such lower temperatures advantageously reduce thermal stresses and shock upon the fabricated structures, specifically, the resulting SIAF 100.

Second conductor 106 serves in part as a capping layer. Moreover, second conductor 106 comprises chromium or another metal (such as titanium and or tungsten) that has good adhesion properties with respect to the amorphous silicon layer 110, and which is electrically conductive. Silver, as either a contiguous layer or as the advantageous silver islands 108, does not have a high adhesion property with respect to amorphous silicon layer 110. In other words the silver in the solid state of the silver islands 108 may separate, or peel away from the amorphous silicon 110. As the second conductor 106 comprises a material with a higher adhesion property than that of the silver islands 108, second conductor 106 intimately couples at least one silver islands 108 to the amorphous silicon layer 110. Moreover, second conductor 106 serve not only to improve the adhesion of the silver islands 108 to the amorphous silicon 110, but also provides electrical continuity between the many silver islands 108 across the surface of the amorphous silicon 110 and the power supply (not shown). As is shown in the figures, in at least one embodiment, the layer of conductive material capping the silver islands 108, such as second conductor 106, is thicker than the silver islands 108.

As indicated above, silver islands 108 may be provided on either side of electrically conductive layer 104 (specifically amorphous silicon layer 110), disposed within one or both electrical conductors 102 and 106. As first conductor 102 and second conductor 106 both comprise material with a higher adhesion property then silver, when silver islands 108 are provided, they will be intimately coupled to electrically resistive material 104 by the conductor in which they are at least partially disposed. Although silver islands 108 may be provided in both first conductor 102 and second conductor 106, the properties of silver are such that it is generally preferable to provide only one set of silver islands 108 within either first conductor 102 or second conductor 106, but not both.

In an initial as-fabricated condition, SIAF 100 has a relatively high resistivity such as, for example, 10^{ˆ10} Ohm-cm, a resistivity typical for intrinsic amorphous silicon as may be used for the electrically resistive material 104. It is understood and appreciated that the actual resistance of SIAF 100 will scale inversely with the device area and directly with the thickness of the amorphous silicon layer 110.

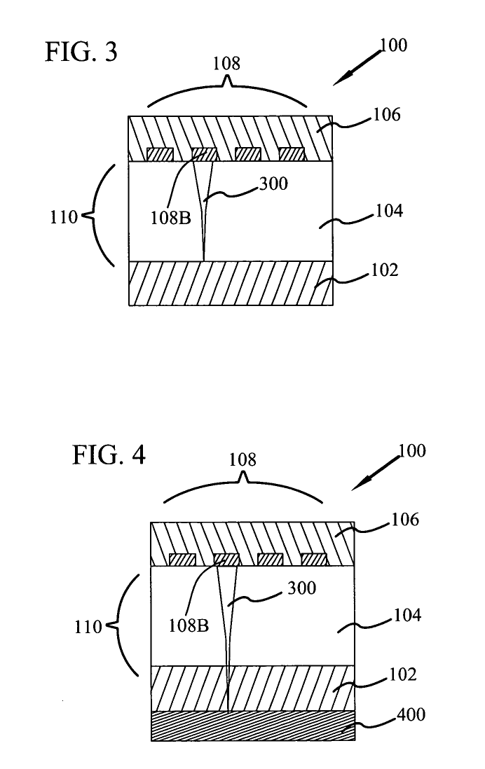

When a critical potential across the SIAF 100 is exceeded, a breakdown occurs and a metallic filament 300 precipitates from at least one silver island, e.g. silver island 108B, through electrically resistive material 104, as shown in FIG. 3. Metallic filament 300 establishes a short through SIAF 100. Metallic filament 300 may be solid silver, or an area of increased electrical conductivity through the electrically resistive material layer 104 formed by a combination of materials including silver. For the purpose of establishing the metallic filament 300 to short SIAF 100, it is immaterial whether the metallic filament develops from one or more silver islands (108A˜108D), or from a specific silver island 108B.

In a shorted condition, the SIAF 100 impedance ranges from several hundred to several thousand ohms, a range easily distinguished from the initial high impedance state of SIAF 100. The reduced level of impedance is also relatively insensitive to the size of SIAF 100 since it depends on the geometry of the filament. This reduced impedance may be sensed as a logical “1” or “0” when the SIAF 100 is incorporated in a memory device.

Testing has shown that metallic filament 300 may not stop at first conductor 102, but may continue propagating through first conductor 102 and into other materials. As a result, in at least one embodiment, a metallic diffusion barrier 400 is in contact with the first conductor 102, opposite from the electrically resistive material 104, see FIG. 4. Moreover, a metallic diffusion barrier 400 is provided opposite from silver islands 108. In at least one alternative embodiment, first conductor 102 comprises appropriate materials to additionally serve as metallic diffusion barrier 400. In other words, may be both a conductor and a diffusion barrier.

Generally, the metallic filament 300 has not shown a propensity to propagate up from the silver islands 108 through the capping conductor, second conductor 106 as shown. However, a metallic diffusion barrier (not shown) may also be provided in contact with the second conductor 106, opposite from the electrically resistive material 104. In at least one embodiment, the metallic diffusion barrier 400, or the combined first conductor 102 diffusion barrier 400 comprises titanium, or an alloy of titanium and tungsten and/or other metals sufficient to arrest metallic filament 300.

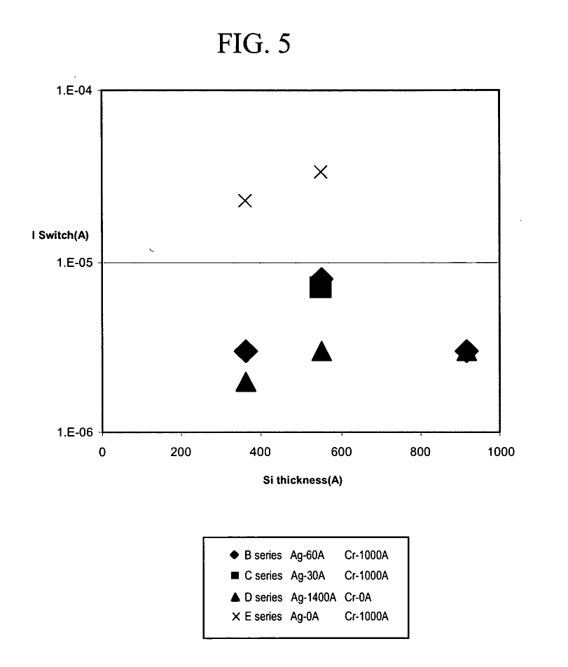

The power required to switch an SIAF 100 with at least one silver island 108 is substantially less than the power required to switch an anti-fuse that does not comprise silver. The graphs provided in FIGS. 5, 6 and 7 are provided to further illustrate this advantageous property for SIAF 100 devices incorporating amorphous silicon layer 110.

Experiments were performed to measure the electrical properties of SIAF 100 with silver island as described above. All of the devices were fabricated on polyimide substrates coated with 1000 Å of sputtered chromium followed by plasma enhanced chemical vapor deposited (“PECVD”) intrinsic amorphous silicon. Three different thickness of amorphous silicon 110 were deposited, 300 Å, 515 Å, and 915 Å. Four different top electrodes were then deposited—1000 Å of sputtered chromium, 1400 Å of sputtered silver, and two composite silver chromium electrodes (silver islands 108 and second conductor 106) as describe above.

One composite silver chrome electrode included 60 Å silver islands and the second included 30 Å silver islands. Lateral conductivity was measured after deposition of the silver and found to be low, verifying the island morphology of the silver. In both cases the silver deposition was followed by 1000 Å of sputtered chromium as the second conductor 106. The four types of top conductors (i.e. the second conductor), are summarized in Table 1.

TABLE 1

| Series | Silver (Ag) | Chromium (Cr) |
|---|---|---|
| B | 60 Å Islands | Cap |
| C | 30 Å Islands | Cap |
| D | Complete Layer | Not Present |
| E | Not Present | Only Layer |

The top conductors 106 were then subsequently patterned using conventional photolithography and wet etching. The resulting SIAF 100 structures are illustrated as cross section FIG. 1 and perspective view FIG. 2 described above. The lateral dimensions of the tested devices ranged from 10 u to 1280 u.

The switching characteristics of the devices were measured on an automatic wafer probing machine. Electrical contact to the bottom electrode was made through a via located a significant distance from the device. The second conductor 106, aka top electrode, was contacted directly with a wafer probe. An Agilent 4155 parameter analyzer was used to force a series of 500 uS duration current pulses through the devices with logarithmically spaced amplitudes varying from 12 uA to 1 mA (typical for 40 u sized devices). The voltage and current required to force the pulses was recorded for both positive and negative polarities. Switching was determined by a substantial reduction in the device impedance, typically by several orders of magnitude.

FIG. 5 illustrates a switching current (I) verses the thickness of the amorphous silicon layer 110 with a positive bias. As shown, silver islands 60 Å in size (represented as diamond points) provide an SIAF 100 with switching properties nearly identical to an anti-fuse with pure silver where the amorphous silicon layer 110 is approximately 390 Å or 900 Å. In all illustrated cases, the presence of silver advantageously results in a lesser switch current than is required in the absence of silver. More importantly, the silver islands are nearly as effective as the pure silver layer.

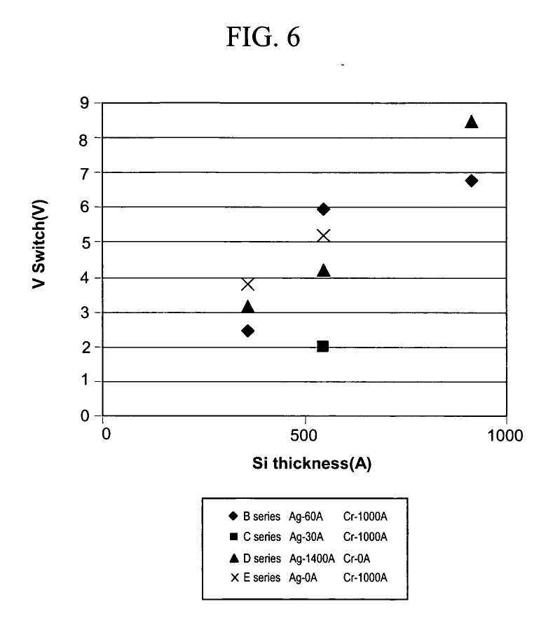

FIG. 6 illustrates a switching voltage (V) versus the thickness of the amorphous silicon layer 104 with a positive bias applied to the Ag/Si interface. More specifically, FIG. 6 illustrates that the voltage at which SIAF 100 switches varies directly with the thickness of the amorphous silicon layer 104. The switching is similar for all devices containing chromium in second conductor 106 and slightly higher for a device with pure silver as second conductor 106.

Because the switching voltage is proportional to the thickness, the switching of SIAF 100 occurs at a critical field of about 1 MV/cm. Unlike the switch current I, shown in FIG. 5, the switch voltage does not depend on the second conductor 106 metal, but rather on the thickness of the amorphous silicon layer 110.

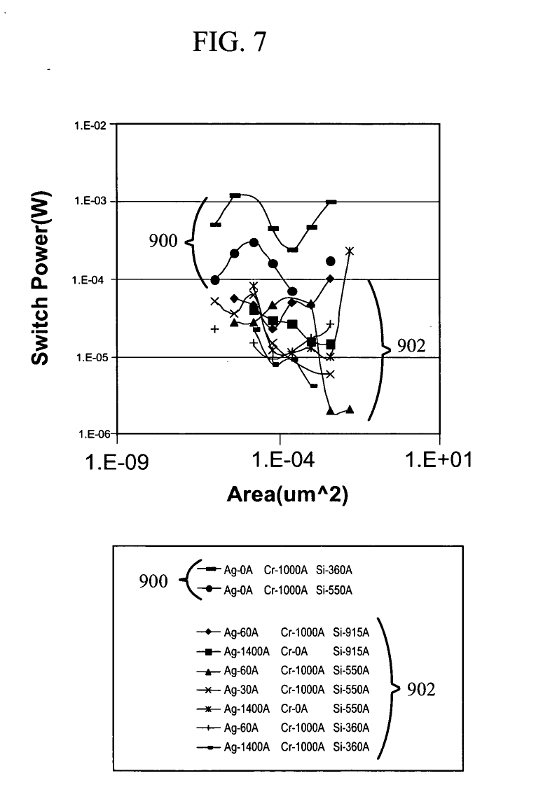

FIG. 7 illustrates the combined effect of scaling switch currents and switch voltages with a positive bias. As shown, second conductors 106 containing silver, either as a continuous layer or as silver islands 108 (group 902), exhibited a switching power significantly below that observed for electrodes containing only chromium (group 900). The composite second conductor 106 as shown in FIGS. 1˜4 therefore provides advantageous and desirable electrical properties of silver electrodes with the adhesion properties of chromium.

As noted above with respect to FIG. 3, the application of a threshold voltage and current induces the development of a metallic filament 300 through electrically resistive material 104, i.e. amorphous silicon layer 110. As shown, the metallic filament 300 develops so that it extends from at least one silver island 108 to the first conductor 102. In this respect, the use of silver islands 108 may be advantageous over a contiguous layer of silver, as the silver islands 108 may permit an element of control regarding the location where metallic filament 300 is likely to develop.

An advantageously simple and highly effective memory device 514 may be provided by coupling SIAF 100 in series with a diode 502, as shown in FIG. 9. As diode 502 may comprise amorphous silicon substantially similar to the amorphous silicon layer 110, the metallic diffusion barrier 400 prevents a developed metallic filament 300 from propagating from SIAF 100 through diode 502.

Diode 502 is typically formed using through similar thin film processes utilized in the fabrication of SIAF 100. More specifically, an appropriate diode 502 may be provided by sputtering a chromium tri layer of Cr/Al/Cr to a thickness of about 1000 Å. Upon this is deposited n+ degeneratively doped microcrystalline Si by PECVD to a thickness of about 600 Å. To this is added about 1600 Å of PECVD intrinsic microcrystalline Si, about 335 Å of PECVD mixed phase (amorphous/microcrystalline) intrinsic Si, and about 300 Å of PECVD P+ degeneratively doped microcrystalline SiC.

SIAF 100 may demonstrate polarity dependence in switching behavior. In other words, if a positive polarity is applied to the first conductor 102 and a negative polarity is applied to the second conductor 106, the SIAF 100 will have one set of switching characteristics. If these polarities are reversed, the switching characteristics may be different, not simply inverted.

Depending upon the ultimate device desired, it may be preferred to forward bias the SIAF 100 in one embodiment while negatively biasing the SIAF 100 in another. It may also be desired to alter the biasing during operation and thus permit SIAF 100 to act as a tertiary state device.

This biasing may be accomplished by varying the coupling order and orientation between the SIAF 100 and the diode 502. In either case, the metallic diffusion barrier 400 is located between the SIAF 100 and the diode 502 to arrest the development of metallic filament 300 when generated within electrically resistive material 104 of SIAF 100.

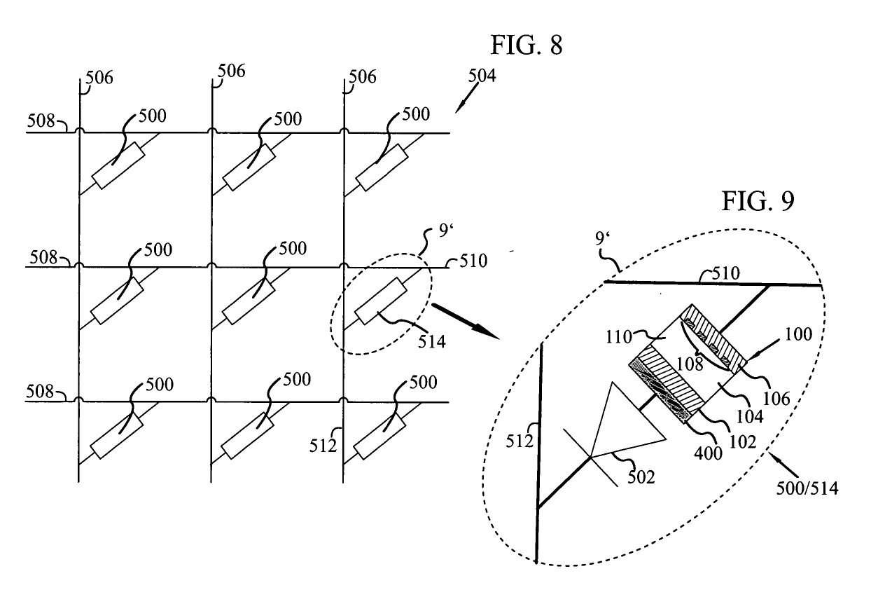

A plurality of memory devices 500 substantially identical to memory device 514, shown as 9′ in FIG. 8, may be incorporated in a memory system 504, comprising a typical matrix of column conductors 506 and row conductors 508 with a memory device 500 at each column/row intersection. Column conductors 506 may also be described as conductive bit lines. Row conductors 508 may also be described as conductive word lines. By selecting a specific row conductor 510 and a specific column conductor 512, a specific memory device 514 may be isolated.

As stated above, the resistance of SIAF 100, and therefore the resistance of memory device 500, is significantly altered by the presence of a metallic filament 300 running through the amorphous silicon layer 104 (see FIG. 3). It is this difference in resistance that is sensed to determine if the memory device 500 is storing a logic state of “0” or a logic state of “1”.

It is understood and appreciated that a convention will be adopted such as, for example, a logic state of “0” exists where SIAF 100 is in an original, as-fabricated state of high resistance (there being no metallic filament 300), and a logic state of “1” exists where SIAF 100 is in a state of low resistance. In at least one embodiment, the determination of resistance is made according to an integration of time. Further, the sensing of resistance may be made repeatedly and averaged to improve the accuracy of detecting the state of resistance.

As illustrated in the charts of FIGS. 5, 6 and 7, SIAF 100 may be switched with less power then a device incorporating no silver. Such reduced power requirements may advantageously results in lower power consumption for the device (such as memory system 504) and less strain on diodes, transistors, conductors and other components that steer power to SIAF 100. This reduced power requirement is especially advantageous where SIAF 100 is incorporated into portable devices.

The simplistic, yet highly reliable nature of SIAF 100 and diode 502 provide a memory device 500 that is easily manufactured at a 100 nano-meter scale, thus cheaply providing large storage capacity devices. As these devices do not require a pre-format by the user before use, they may be used immediately upon insertion or connection to the memory requiring device. As such, these devices may provide a user with a faster-time- to-service then would otherwise be enjoyed with an unformatted or unchecked re-writeable device.

In addition, although limited to a single switch from high resistance to low resistance, the low cost of fabrication will result in low cost to the consumer, the write once nature thereby providing an attractive alternative to more expensive, re-writable devices when and where such re-writeability is not truly desired or beneficial. As such, SIAF 100 and devices such as memory device 500 are likely to result in a savings of resources, manufacturing time and associated costs when and where SIAF 100 is employed over a re-writeable device.

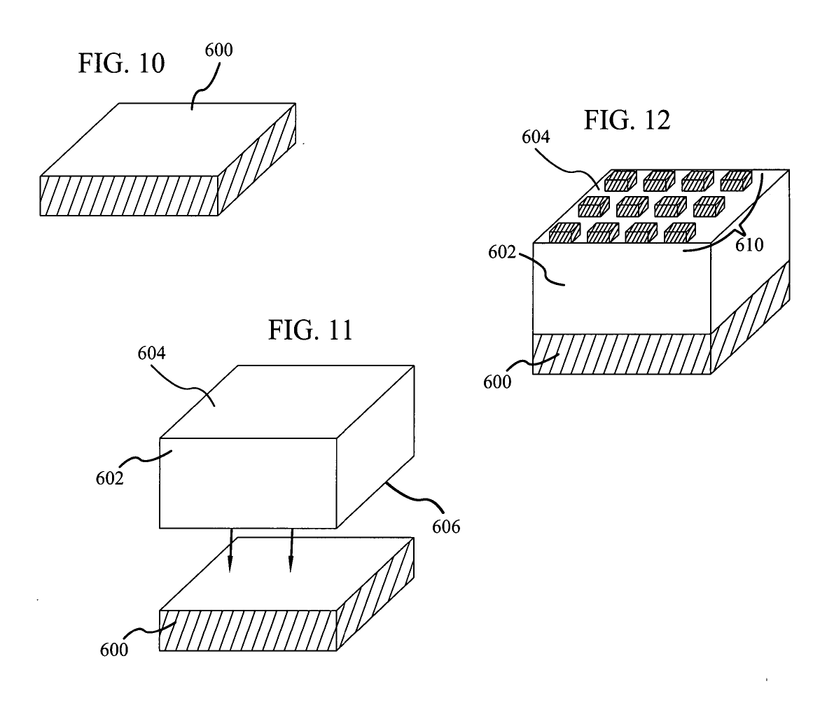

Having described the individual components of SIAF 100, a preferred method of fabricating SIAF 100 will now be described as illustrated in FIGS. 10 thorough 15. It will be appreciated that the described method need not be performed in the order in which it is herein described, but that this description is merely exemplary of one method of fabricating an embodiment of SIAF 100.

As shown in FIG. 10, in at least one embodiment, the method of fabrication is commenced by providing a first conductor 600. First conductor 600 is an electrically conductive material and, in at least one embodiment, comprises chromium, though other appropriate electrically conductive materials may also be employed. First conductor 600 may be provided upon a previously fabricated wafer or device, such as a thin film structure, diode, or other device. In at least one embodiment, first conductor 600 is provided by sputtering about 1000 Å of chromium upon a substrate, not shown.

A resistive material 602 is then deposited upon first conductor 600. In at least one embodiment, the resistive material 602 is intrinsic amorphous silicon deposited by PECVD, to a thickness of about 550 Å and is substantially equivalent to the amorphous silicon layer 110 discussed above. Resistive material 602 may be further described as having a first side 604, and opposite thereto, a second side 604. Resistive material 602 is, for example, resistive material 104, FIGS. 1˜4. As shown in FIG. 11, when resistive material 602 is deposited upon first conductor 600, second side 604 will be in intimate contact with first conductor 600.

A thin layer of silver is deposited upon the first side 604 of resistive material 602. Again as noted above, if the layer of silver is less than 100 Å in thickness, it will not form a continuous film, but rather will form the advantageous plurality of silver islands 610 (see FIG. 12) that are substantially similar to the silver islands 108 described above. Moreover, in at least one embodiment, the layer of silver deposited is less than 100 Å. The tendency of silver to create silver islands 610 alleviates the need to perform a pattern and etch process to achieve the desired silver islands 610. In other words, patterning is not required to provide the latterly discontinuous silver islands 610. In at least one embodiment, the silver islands 610 are deposited by sputtering an about 60 Å of silver upon the resistive material 602.

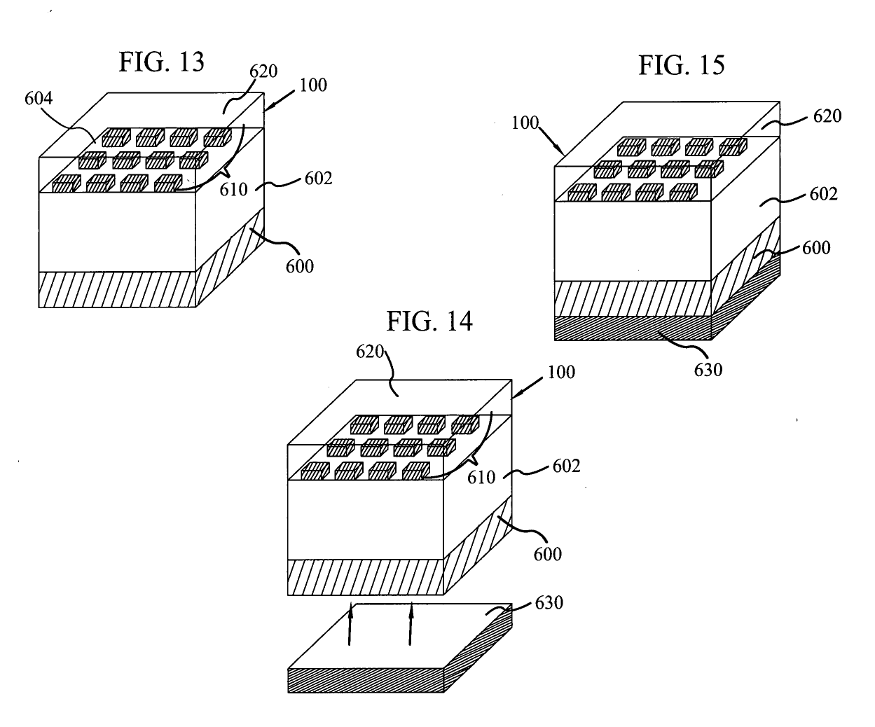

As silver, including silver islands 610, has a relatively weak adhesion property with respect to the resistive material 602, i.e. an amorphous silicon layer, a conductive material 620 having a greater adhesion property is deposited over silver islands 610 and upon first side 604 of resistive material 602, see FIG. 13. In at least one embodiment, conductive material 620 includes chromium. Further, in at least one embodiment, the conductive material 620 is 1000 Å of sputtered chromium.

As shown, the conductive material 620 substantially surrounds all silver islands 610. However, it is understood and appreciated that conductive material 620 may be applied to cover a subset of silver islands 610. The combined structure of conductive material 620 and covered silver islands 610 provides a top conductor for the resulting fabricated SIAF 100.

In at least one embodiment, so as to halt unintended propagation of a metallic filament 300 (see FIG. 3) developed by the application of a threshold voltage and current through the resistive material 602 from at least one silver island 610, first conductor 600 may be comprised of titanium, or an alloy of titanium and tungsten and/or other metals sufficient to arrest metallic filament 300.

In an alternative embodiment, first conductor 600 may be deposited (as by sputtering) in electrical contact upon a metallic diffusion barrier 630, see FIG. 14. First conductor 600 may be deposited upon metallic diffusion barrier 630 before resistive material 602 is deposited, or at a conveniently appropriate point in the fabrication of SIAF 100. The resulting fabricated SIAF 100 with a distinct diffusion barrier 630 is illustrated in FIG. 15. Again it is appreciated that first conductor 600 may comprise materials sufficient to provide the first conductor 600 as a metallic diffusion barrier.

Under appropriate circumstances, a metallic diffusion barrier 640 may be deposited in contact with conductive material 620 in addition to or in place of a metallic diffusion barrier 640 deposited upon second conductor 630. In at least one embodiment, the metallic diffusion barrier 640 comprises titanium, tungsten, titanium/tungsten, and/or other metals sufficient to arrest the developed metallic filament 300.

As discussed and described above, in at least one preferred embodiment the component layers of SIAF 100 (first conductor 600, silver to establish silver islands 610, conductive material 620 upon the silver islands 610, and metallic diffusion barrier 640) are deposited primarily by sputtering and PECVD via roll-to-roll deposition equipment. Under appropriate circumstances alternative methods of material application commonly employed in thin film fabrication may be employed, such as for example, spin casting, ion beam deposition, electron beam evaporation, roll to roll film application, metal organic deposition (MOD), chemical vapor deposition (CVD), or such other appropriate methods. The choice of method will be appropriately determined by the material involved and the preference of the fabrication engineer.

Changes may be made in the above methods, systems and structures without departing from the scope hereof. It should thus be noted that the matter contained in the above description and/or shown in the accompanying drawings should be interpreted as illustrative and not in a limiting sense. The following claims are intended to cover all generic and specific features described herein, as well as all statements of the scope of the present method, system and structure, which, as a matter of language, might be said to fall therebetween.

We claim:

1. A silver island anti-fuse, comprising:
a first electrical conductor;
an electrically resistive material in contact with the first electrical conductor;
a second electrical conductor in contact with the electrically resistive material layer, opposite from the first electrical conductor; and
a plurality of silver islands at least partially disposed within one or both electrical conductors, the silver islands in contact with the electrically resistive material.

2. The silver island anti-fuse of claim 1, wherein the first electrical conductor and second electrical conductor have an adhesion property greater than silver.

3. The silver island anti-fuse of claim 1, wherein the silver islands are less than 100 Å thick.

4. The silver island anti-fuse of claim 1, wherein the electrically resistive material includes amorphous silicon layer.

5. A silver island anti-fuse, comprising:
a first electrical conductor;
an electrically resistive material in contact with the first conductor;
at least one silver island disposed upon the electrically resistive material, opposite from the first electrical conductor; and
a second electrical conductor disposed over the at least one silver island, the second electrical conductor intimately coupling the at least one silver island and the electrically resistive material.

6. The silver island anti-fuse of claim 5, wherein the electrically resistive material includes amorphous silicon layer.

7. The silver island anti-fuse of claim 5, wherein the second electrical conductor has an adhesion property greater than silver.

8. The silver island anti-fuse of claim 5, wherein the second electrical conductor comprises chromium.

9. The silver island anti-fuse of claim 5, wherein the second electrical conductor and at least one silver island form an electrically continuous layer in contact with the electrically resistive material.

10. The silver island anti-fuse of claim 5, operable as a switch where the application of a threshold voltage and current inducing the development of a metallic filament through the electrically resistive material from at least one silver island to induce a short through the electrically resistive material.

11. The silver island anti-fuse of claim 5, wherein the first electrical conductor includes a metallic diffusion barrier.

12. The silver island anti-fuse of claim 5, wherein the at least one silver island is less than 100 Å thick.

13. The silver island anti-fuse of claim 5, further including a metallic diffusion barrier in contact with the second electrical conductor, opposite from the electrically resistive material.

14. The silver island anti-fuse of claim 13, wherein the metallic diffusion barrier comprises titanium, tungsten, and/or titanium/tungsten.

15. The silver island anti-fuse of claim 5, wherein the anti-fuse couples to a diode in series through a metallic diffusion barrier to provide a memory device.

16. A memory device, comprising:
a diode;
a metallic diffusion barrier having a first and second side, the diode electrically coupled to the first side;
a silver island anti-fuse electrically coupled to the second side of the metallic diffusion barrier, the silver island anti-fuse including:
a first electrical conductor;
an electrically resistive material in contact with the first conductor;
at least one silver island disposed upon the electrically resistive material layer, opposite from the first electrical conductor; and
a second electrical conductor disposed over the at least one silver island, the second electrical conductor intimately coupling the at least one silver island to the electrically resistive material.

17. The memory device of claim 16, wherein the second electrical conductor of the anti-fuse is coupled to the metallic diffusion barrier.

18. The memory device of claim 16, wherein the metallic diffusion barrier is the second electrical conductor.

19. The memory device of claim 16, wherein the second electrical conductor has an adhesion property greater than silver.

20. The memory device of claim 16, wherein the second electrical conductor and at least one silver island form an electrically continuous layer in contact with the electrically resistive material.

21. The memory device of claim 16, wherein the second electrical conductor comprises chromium.

22. The memory device of claim 16, further comprising an array of electrically coupled diodes and silver island anti-fuses.

23. The memory device of claim 16, wherein the first electrical conductor of the anti-fuse is coupled to the metallic diffusion barrier.

24. The memory device of claim 23, wherein the metallic diffusion barrier comprises titanium, tungsten, and/or titanium/tungsten.

25. A method of making an silver island anti-fuse, comprising:
providing a first conductor;
depositing an electrically resistive material upon the first conductor;
depositing a thin layer of silver upon the electrically resistive material layer, opposite from the first conductor, the layer of silver sufficiently thin so as to form a plurality of silver islands upon the first side of the electrically resistive material layer; and
disposing a conductive material over the silver islands and upon the electrically resistive material layer, the conductive material intimately adhering the silver islands to the electrically resistive material.

26. The method of claim 25, wherein the electrically resistive material is an amorphous silicon layer.

27. The method of claim 25, wherein the first conductor is provided upon a previously fabricated substrate or device.

28. The method of claim 25, wherein the conductive material has an adhesion property greater than silver.

29. The method of claim 25, wherein the conductive material and plurality of silver islands form an electrically continuous layer in contact with the electrically resistive material.

30. The method of claim 25, wherein the thin layer of silver deposited is less than 100 Å thick.

31. The method of claim 25, further including providing a metallic diffusion barrier in contact with the second conductor opposite from the electrically resistive material layer, or in contact with the conductive material opposite from the electrically resistive material.

32. The method of claim 31, wherein the metallic diffusion barrier comprises titanium, tungsten, and/or titanium/tungsten.

33. The method of claim 25, wherein the second conductor further comprises materials sufficient to provide the second conductor as a metallic diffusion barrier.

34. The method of claim 25, wherein the deposited silver layer is not pattered to provide the laterally discontinuous silver islands.
